(19) United States
(12) Patent Application Publication
(10) Pub. No.: US 2007/0290340 A1
(43) Pub. Date: Dec. 20, 2007

(54) CHIP STRUCTURE

(75) Inventors: Jen-Hao Hsueh, Taichung City (TW); Feng-Jung Kuo, Taipei County (TW); Wen-Ping Chou, Hsinchu County (TW); Hsiang-Yi Liu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: NOVATEK MICROELECTRONICS CORP., Hsinchu (TW)

(21) Appl. No.: 11/468,304

(22) Filed: Aug. 30, 2006

(30) Foreign Application Priority Data
Jun. 14, 2006 (TW) 95121192

(51) Int. Cl. H01L 23/48

(52) U.S. Cl. 257/737; 257/E23.021

(57) ABSTRACT

A chip structure including a chip, at least an arrangement of side pads and multiple bumps is provided. The chip has an active surface, and the arrangement of side pads is disposed on the active surface and close to a side of the active surface. The arrangement of side pads includes multiple pads arranged along the extending direction of the side, and the bumps are disposed on the pads. Each bump has a first portion and a second portion, wherein the second portion is connected to the first portion along an axis perpendicular to the extending direction of the side. In addition, the width of the first portion in the extending direction of the side is larger than that of the second portion in the extending direction of the side. The second portion of the bump is located between the first portions of two bumps adjacent to the bump.

### CROSS-REFERENCE TO RELATED APPLICATION

This application claims the priority benefit of Taiwan application serial no. 95121192, filed on Jun. 14, 2006. All disclosure of the Taiwan application is incorporated herein by reference.

### BACKGROUND OF THE INVENTION

1. Field of Invention

The present invention relates to a semiconductor structure, and more particularly, to a chip structure.

2. Description of Related Art

Recently, since the volume of the data required to be displayed by the display has been increased significantly, the driver IC for driving the panel must have a high input/output (I/O) terminal. Moreover, the size requirement of the liquid crystal display (LCD) must be considered in the design of the driving IC, thus, the driving IC of the liquid crystal panel is generally designed into strip shape, such that the number of the I/O terminals disposed on the edge of the driving IC can be increased, while considering the size requirement of the LCD. The driving IC of the current LCD is generally bonded to the liquid crystal panel by way of Chip On Glass (COG), Chip On Film (COF) or Tape Automated Bonding (TAB).

FIG. 1A is a top view of a conventional chip structure, and FIG. 1B is a cross-section view of the chip structure in FIG. 1A taken along the section line A-A′. Referring to both FIG. 1A and FIG. 1B, a conventional chip structure 100 comprises a chip 110, a plurality of pads 120 disposed on an active surface 112 of the chip 110, and a plurality of bumps 130, wherein the bumps 130 are disposed on the corresponding pads 120. In the conventional art, a probe card disposed within the test stand is used to perform an electrical test for the chip structure 100 (the probes of the probe card contacts with the bumps 130 in the chip structure 100 to perform the electrical test), wherein the bump width W of the bumps 130 meets the detection specification requirements of the probes, such that the pin of the probe can be efficiently in contact with the bumps 130 having the bump width W to perform the electrical test. Further, since the pads 120 are arranged on the side of the chip 110 in a single row, the size of the chip structure 100 varies depending on the number of the pads 120 and the size of the bump pitch, wherein the bump pitch P1 of the chip structure 100=bump width W+bump space S.

In order to make the chip structure 100 have a small size, the width of the bumps 130 is reduced in the conventional art, so as to reduce the bump pitch. However, when using the probe card to perform electrical test for the chip structure 100, since the bump width is reduced, the pin diameter of the probe may be larger than the bump width. Therefore, when the probes are used to test the chip structure 100, it is not easy for the probes to be aligned with the bumps 130, thus causing alignment offset or poor contact (e.g., the circumstance that a probe contacts with two adjacent bumps).

### SUMMARY OF THE INVENTION

An objective of the present invention is to provide a chip structure, such that the chip has a small size, and meanwhile the electrical test of the chip structure is considered.

In order to achieve the above or other objectives, the present invention provides a chip structure, which comprises a chip, at least an arrangement of side pads and a plurality of bumps, wherein the chip has an active surface, and the arrangement of side pads is disposed on the active surface and close to a side of the active surface. The arrangement of side pads includes a plurality of pads equidistantly arranged along the extending direction of the side. The bumps are disposed on the pads, and are also equidistantly arranged along the extending direction of the side. Each bump has a first portion and a second portion, wherein the second portion is connected to the first portion along an axis perpendicular to the extending direction of the side. In addition, the width of the first portion in the extending direction of the side is larger than that of the second portion in the extending direction of the side, and the second portion of the bump is located between the first portions of two bumps adjacent to this bump.

In an embodiment of the present invention, the chip structure further comprises a protective layer, wherein the protective layer has a plurality of openings for exposing the pads.

In an embodiment of the present invention, the shape of the opening is the same as that of the bump.

In an embodiment of the present invention, the bumps are gold bumps.

In an embodiment of the present invention, the shapes of the first portion and the second portion are rectangular.

In an embodiment of the present invention, the length of the first portion in the axis direction is less than that of the second portion in the axis direction.

In an embodiment of the present invention, the length of the first portion in the axis direction equals to that of the second portion in the axis direction.

In an embodiment of the present invention, the length of the first portion in the axis direction is larger than that of the second portion in the axis direction.

In an embodiment of the present invention, the pads are equidistantly arranged along the extending direction of the side.

In the chip structure of the present invention, the width of the first portion of the bump in the extending direction of the side is larger than that of the second portion of the bump in the extending direction of the side, and the second portion of the bump is located between the first portions of two bumps adjacent to this bump. Therefore, compared with the conventional art, the chip structure of the present invention has a smaller bump pitch, such that the chip structure has a smaller size. In addition, the bump width of the first portion meets the size requirement of the probe used for the electrical test, thus, the probes within the probe card can be effectively in contact with the bumps to perform the electrical test.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a conventional chip structure.

FIG. 1B is a schematic view of the chip structure in FIG. 1A taken along the section line A-A′.

FIG. 2A is a top view of a chip structure according to a preferred embodiment of the present invention.

FIG. 2B is a schematic view of the chip structure in FIG. 2A taken along the section line B-B′.

### DESCRIPTION OF EMBODIMENTS

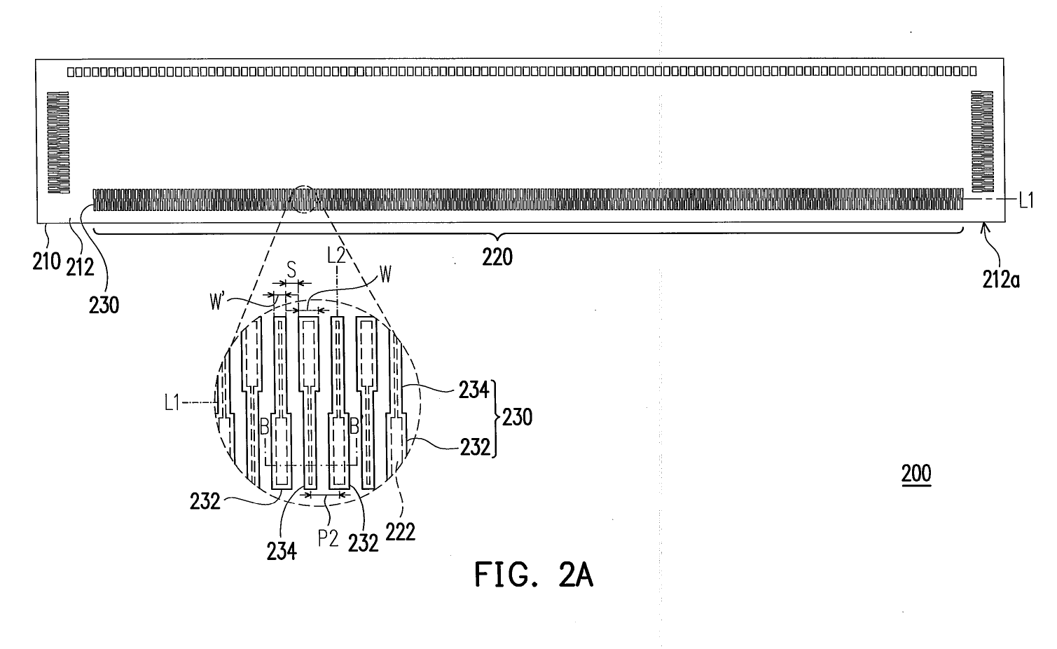

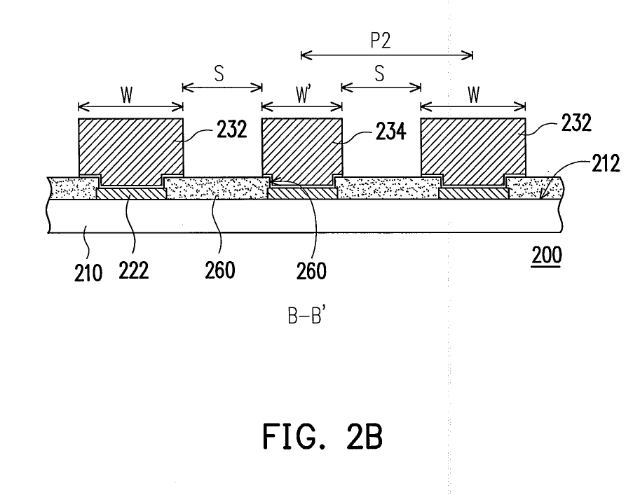

FIG. 2A is a top view of a chip structure according to a preferred embodiment of the present invention, and FIG. 2B is a cross-section view of the chip structure in FIG. 2A taken along the section line B-B′. Referring to both FIG. 2A and FIG. 2B, the chip structure 200 of this embodiment is, for example, a driving IC, which mainly comprises a chip 210, at least an arrangement of side pads 220 and a plurality of bumps 230, wherein the chip 210 has an active surface 212, and the material of the bumps 230 is, for example, gold. In this embodiment, the arrangement of side pads 220 is disposed on the active surface 212 and close to a side 212a of the active surface 212. The arrangement of side pads 220 comprises a plurality of pads 222 arranged along the extending direction L1 of the side 212a. In an embodiment, the pads 222 are, for example, equidistantly arranged along the extending direction L1 of the side 212a. In addition, the bumps 230 are disposed on the pads 222, and the bumps 230 are also equidistantly arranged along the extending direction L1 of the side 212a.

In this embodiment, each bump 230 has a first portion 232 and a second portion 234, wherein the second portion 234 is connected to the first portion 232 along an axis L2 perpendicular to the extending direction L1 of the side 212a. In addition, the shape of the first portion 232 and the second portion 234 is, for example, rectangular, or other suitable shapes. It should be noted that, the bump width W of the first portion 232 of the bump 230 in this embodiment, for example, satisfies the test size requirements of the probe card (not shown). For example, the bump width W is, for example, larger than or equal to the diameter of the pin of the probe. Therefore, when the probe is used to perform the test for the chip structure 200, the probe is aligned with the bump 230, and the pin of the probe effectively contacts with the first portion 232 having the bump width W, so as to perform the electrical test.

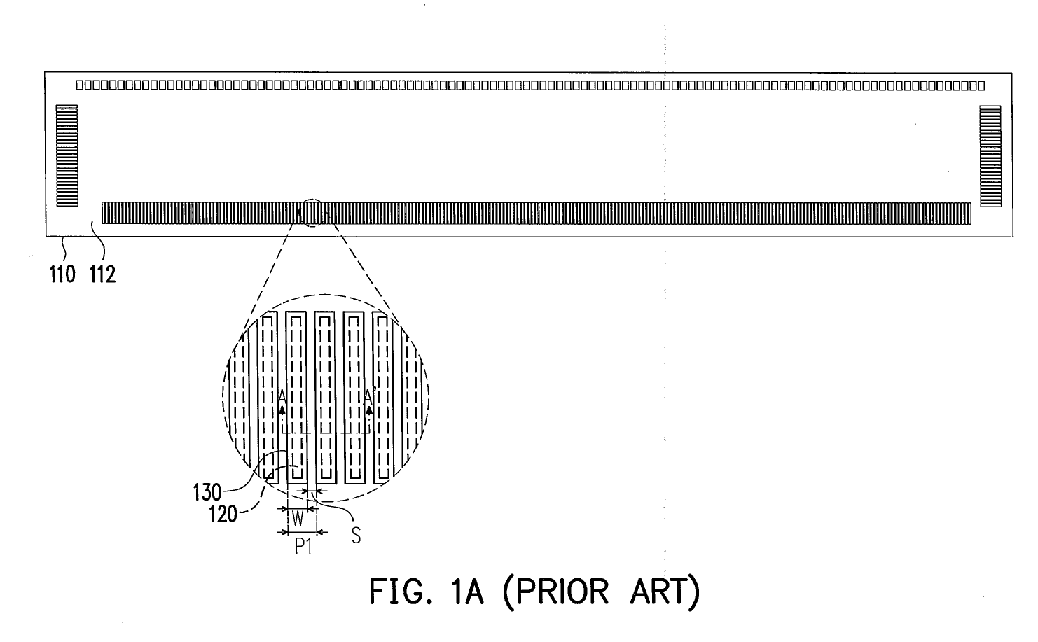

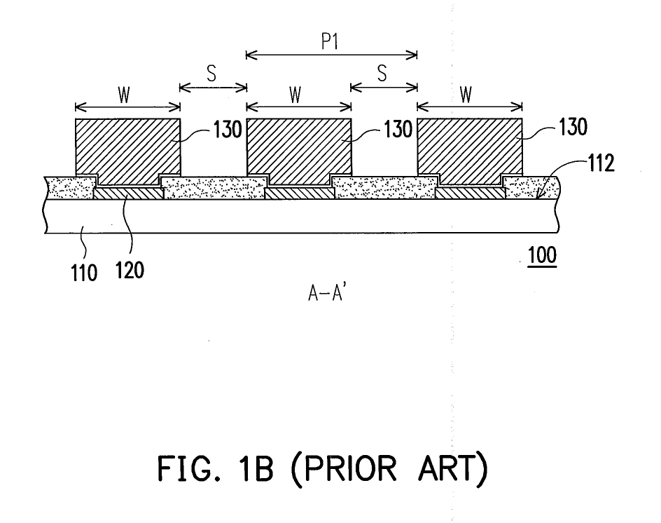

Furthermore, in this embodiment, the width W′ of the second portion 234 of the bump 230 in the extending direction of the side 212a is less than the width W of the first portion 232 in the extending direction of the side 212a, and the second portion 234 of the bump 230 is located between the first portions 232 of two bumps 230 adjacent to the bump 230. Therefore, the bump pitch P2 of the chip structure 200 in this embodiment is the sum of a half of the bump width W of the first portion, a half of the bump width W′ of the second portion and the bump space S. Since the bump width W′ is less than the bump width W, the bump pitch P2 of this embodiment is less than the bump pitch P1 of the conventional chip structure 100 (shown in FIG. 1A). As such, under the condition of having the same number of pads, the chip structure 200 of this embodiment has a smaller size compared with the conventional chip structure 100. In addition, the length of the bump 230 in the axis direction L2 is not limited in this embodiment. For example, the length of the first portion 232 of the bump 230 in the axis direction L2 can be less than, equal to or larger than that of the second portion 234 in the axis direction L2.

In a preferred embodiment, the chip structure 200 may comprise a protective layer 260, wherein the protective layer 260 covers the chip 210, and has a plurality of openings 262 for exposing the pads 220, and the shape of the openings 262 can be the same as that of the bumps 230.

To sum up, in the chip structure of the present invention, the width of the second portion of the bump in the extending direction of the side is less than that of the first portion in the extending direction of the side, and the bump width of the first portion satisfies the probe size requirements of the electrical test. In addition, the second portion of the bump is located between the first portions of two bumps adjacent to this bump. Therefore, the chip structure of the present invention has a smaller bump pitch. In comparison with the conventional art, the chip structure of the present invention has the following advantages.

1. The bump pitch of the present invention is smaller, thus the chip structure has a smaller size.

2. The bump width of the first portion of the bump satisfies the probe size requirements of the electrical test, thus, during the electrical test for the chip structure, the probe is accurately aligned with the first portion of the bump, that is to say, the probe card disposed within the test stand can be effectively in contact with the bumps for performing the electrical test.

As can be known from the above, the present invention can reduce the size of the chip structure, while considering the electrical test for the chip structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip structure, comprising:
a chip, having an active surface;
at least an arrangement of side pads, disposed on the active surface and close to a side of the active surface, wherein the arrangement of side pads comprises a plurality of pads arranged along the extending direction of the side;
a plurality of bumps, disposed on the pads and equidistantly arranged along the extending direction of the side, wherein each of the bumps comprises:
a first portion; and
a second portion, connected to the first portion along an axis perpendicular to the extending direction of the side, wherein the width of the first portion in the extending direction of the side is larger than the width of the second portion in the extending direction of the side, and the second portion of each of the bumps is located between the first portions of two bumps adjacent to the bump.

2. The chip structure as claimed in claim 1, further comprising a protective layer, wherein the protective layer covers the chip and has a plurality of openings for exposing the pads.

3. The chip structure as claimed in claim 2, wherein the shape of the openings is the same as that of the bumps.

4. The chip structure as claimed in claim 1, wherein the bumps are gold bumps.

5. The chip structure as claimed in claim 1, wherein the shape of the first portion and the second portion is rectangular.

6. The chip structure as claimed in claim 1, wherein the length of the first portion in the axis direction is less than that of the second portion in the axis direction.

7. The chip structure as claimed in claim 1, wherein the length of the first portion in the axis direction is equal to that of the second portion in the axis direction.

8. The chip structure as claimed in claim 1, wherein the length of the first portion in the axis direction is larger than that of the second portion in the axis direction.

9. The chip structure as claimed in claim 1, wherein the pads are equidistantly arranged along the extending direction of the side.
